(19) United States
(12) Patent Application Publication
(10) Pub. No.: US 2010/0244868 A1
(43) Pub. Date: Sep. 30, 2010

(54) Wireless Clamp-on Current Probe

(75) Inventors: Guilford L. CANTAVE, Orlando, FL (US); Steven M. FRANCESCHINI, Casselberry, FL (US)

Correspondence Address: THOMAS F. LENIHAN;TEKTRONIX, INC., 14150 S. W. KARL BRAUN DRIVE, P.O. BOX 500 (50-LAW), BEAVERTON, OR, 97077-0001, US

(73) Assignee: TEKTRONIX, INC., Beaverton, OR (US)

(21) Appl. No.: 12/720,055

(22) Filed: Mar. 9, 2010

Related U.S. Application Data
(60) Provisional application No. 61/211,143, filed on Mar. 26, 2009.

(51) Int. Cl. G01R 31/02

(52) U.S. Cl. 324/754

(57) ABSTRACT

A Wireless Clamp-on Current Probe and an embedded system which includes a digital RF transceiver allows for remote test and measurement equipment to receive data from a current probe without regard to cabling issues such as size, physical wear, weight, cost, electrical noise, losses and more. Such a current probe may be used in environments and situations not previously explored. The probe may be controlled and queried by wired serial communication means or by means of an integrated radio frequency (RF) transceiver. The RF transceiver may utilize a proprietary communication protocol or a standard wireless communication protocol such as ZigBee, Bluetooth or any of the IEEE communication standards.

### CROSS REFERENCE TO RELATED PATENT APPLICATIONS

This application claims priority to U.S. Provisional Application Ser. No. 61/211,143 filed on Mar. 26, 2009, which is incorporated herein by reference in its entirety.

### FIELD OF THE INVENTION

The invention relates generally to an apparatus and method for measuring the magnitude of an electrical current. In particular, the apparatus and the method of the present invention provide measurement of electrical current by a clamp-on current probe.

### BACKGROUND OF THE INVENTION

Clamp-on current probes are used to make noncontact current measurements of the current passing through a conductor without interrupting the electrical circuit being tested. Other methods of measuring current passing through a conductor include the use of shunt resistors. The drawbacks of using shunt resistors include but are not limited to inherent power losses, the need to interrupt the circuit path to insert the meter in-line, heat generation, and the absence of electrical isolation from the circuit under test. U.S. Pat. No. 7,362,086 (Dupuis, et al.) entitled, INTEGRATED CURRENT SENSOR, issued 22 Apr. 2008, describes a variety of method for detecting current at a particular point in a circuit including utilizing coupled inductors for generating an output current responsive to a detected current.

U.S. Pat. No. 5,493,211 (Clifford Baker) entitled, CURRENT PROBE, issued 20 Feb. 1996 and assigned to the same assignee as the current invention, describes a current probe employing a Hall Effect Sensor for measuring the current in a conductor.

Clamp-on current probes are normally connected to test equipment such as digital multimeters, oscilloscopes, data acquisition units, power meters and other various instruments using banana jacks or other forms of cabling. Some clamp-on current probes are totally self contained and have visual indication of the magnitude of the current being measured, but do not have a means of connecting to external instruments.

Unfortunately, there are certain circumstances in which the use of such a wired interface between a current probe and a test and measurement instrument, or a data collection instrument, may be undesirable, or even dangerous to the user.

### SUMMARY OF THE INVENTION

The apparatus and method of the present invention perform non-contact measurements of the current passing through a conductor without interrupting the electrical circuit being tested, and wirelessly transmit the measured data to a receiving unit. The apparatus of the present invention, when clamped around a conductor, can measure the current passing through the conductor and wirelessly transmit the data to a receiving unit. The apparatus of the present invention may transfer this data to a data acquisition system, a test and measurement instrument or other host apparatus, in which the receiving unit can be embedded. The information received by the receiving unit can be made available on demand or can optionally be logged.

The wireless clamp-on current probe of the present invention combines a clamp-on current probe with an embedded system which includes an RF transceiver to enable stationary test equipment to connect to current probes, without regard to cabling issues such as size, physical wear of cables, weight, cost, electrical noise, losses and other issues related to physical connections. The apparatus and method of the present invention also permit the use of current probes in environments and situations not previously possible.

The apparatus of the present invention may be controlled and queried by wired serial communication means or by an integrated radio frequency (RF) transceiver. The RF transceiver may utilize a proprietary communication protocol or a standard wireless communication protocol such as ZigBee, Bluetooth or any of the IEEE communications standards. The many configuration settings of the apparatus may be changed by the user by issuing commands to the apparatus from an established command set. The apparatus of the present invention may use digital processors for signal processing to perform all core functions. This enables the apparatus to add functionality in the form of modified firmware instead of modifying existing circuitry or adding further circuitry.

### BRIEF DESCRIPTION OF THE DRAWINGS

FIG. 1 is a basic high-level block diagram of the transmitter system of one embodiment of the invention.

FIG. 2A is a schematic of the transmitter analog front end portion of one embodiment of the system of the invention.

FIG. 2B is a schematic of the transmitter +2.5V voltage reference portion of one embodiment of the system of the invention.

FIG. 2C is a schematic of the transmitter analog-to-digital (ADC) converter portion of one embodiment of the system of the invention.

FIG. 2D is a schematic of the transmitter microcontroller portion of one embodiment of the system of the invention.

FIG. 2E is a schematic of the transmitter +3.3V buck-boost DC-DC converter portion of one embodiment of the system of the invention.

FIG. 2F is a schematic of the transmitter +3.3V rail on after delay portion of one embodiment of the system of the invention.

FIG. 2G is a schematic of the transmitter −15V boost DC-DC inverter portion of one embodiment of the system of the invention.

FIG. 2H is a schematic of the transmitter +15V boost DC-DC converter portion of one embodiment of the system of the invention.

FIG. 2I is a schematic of the transmitter Lithium-Ion/Lithium-Polymer charge management controller portion of one embodiment of the system of the invention.

FIG. 2J is a schematic of the transmitter digital RF transceiver portion of one embodiment of the system of the invention.

FIG. 3A is the transmitter basic high-level firmware flowchart of one embodiment of the invention.

FIGS. 3B and 3C form a single table of the standard system commands which may be used to operate the unit.

FIG. 4 is a basic high-level block diagram of the receiving system for one embodiment of the invention.

FIG. 5A is a schematic of the receiver analog front end portion of one embodiment of the system of the invention.

FIG. 5B is a schematic of the receiver +2.5V voltage reference portion of one embodiment of the system of the invention.

FIG. 5C is a schematic of the receiver microcontroller portion of one embodiment of the system of the invention.

FIG. 5D is a schematic of the receiver +3.3V regulators of one embodiment of the invention.

FIG. 5E is a schematic of the receiver digital RF transceiver portion of one embodiment of the system of the invention.

FIG. 6A is the receiver basic high-level firmware flowchart of one embodiment of the invention.

FIG. 6B is a further table of the standard system commands which may be used to operate the unit.

FIG. 7 is an isometric depiction of a wireless clamp-on current probe in accordance with the subject invention.

FIG. 8 is an isometric depiction of a wireless clamp-on current probe receiver unit in accordance with the subject invention.

### DETAILED DESCRIPTION OF THE INVENTION

The apparatus and method of the present invention can be used to make noncontact current measurements of the current passing through a conductor without interrupting the electrical circuit being tested, and wirelessly transmit the measured data to a receiving unit. The apparatus of the present invention can be clamped onto a conductor to measure the current passing through it and wirelessly transmit the measured current value to a receiver unit. This information can be made available on demand or optionally logged.

The apparatus of the present invention may include a variety of elements arranged in different combinations depending on the use of the apparatus. Such elements that may be found in the apparatus of the present invention include, but are not limited to, voltage regulators, precision voltage references, radio transceivers, battery charge management controllers, lithium batteries, microcontrollers, nonvolatile memory, analog-to-digital converters, Hall Effect sensors, instrumentation amplifiers, operational amplifiers and other elements that optimize the apparatus for particular uses.

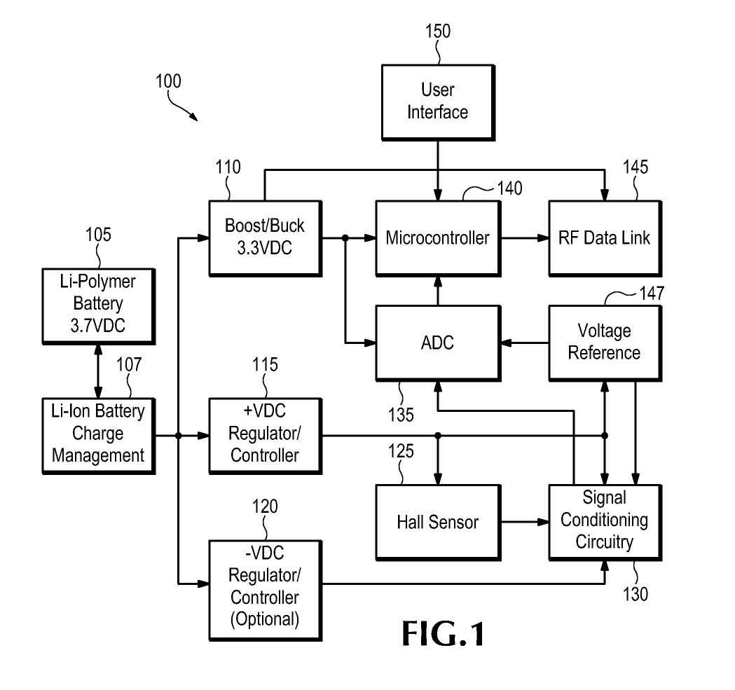

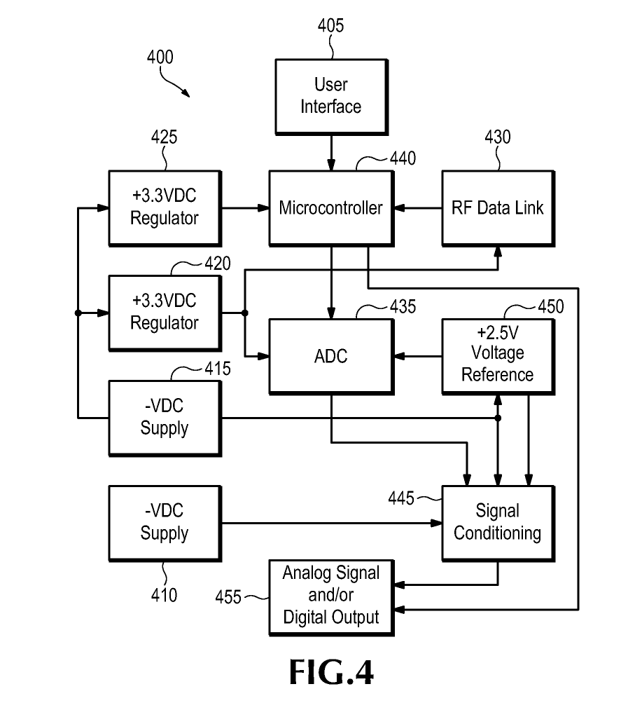

FIG. 1 is a basic high-level block diagram of the transmitter system 100 of one embodiment of the invention which illustrates the relationship between all of the major sub-circuits of the system such as power, analog, digital and RF. The primary source of power for the transmitting unit is a lithium battery 105 which has a voltage span from 4.2V when fully charged to approximately 3.0V when depleted. Voltage regulators are employed to regulate the supply voltage from lithium battery 105, because the voltages used by the subsystems need to be fixed at particular voltage levels. The apparatus of the present invention includes +3.3V, +15V and −15V switch-mode voltage regulators 110, 115, 120 which supply the required constant voltages to all of the subsystems, even as the battery voltage decreases while the unit is in use. A Hall Effect sensor 125 may be used as a transducer for converting the magnitude of a detected magnetic field generated by the current carrying conductor, to a representative voltage. A signal conditioning circuit 130 filters and scales the output voltage from the Hall Effect sensor to a magnitude which is appropriate for the input range of an ADC (analog-to-digital converter) 135. ADC 135 converts the output voltage from the signal conditioning circuitry into digital data. This digital data is applied to a microcontroller 140 for processing and formatting and then sent serially to an RF data link 145 for wireless transmission to the receiving unit 400 (of FIG. 4).

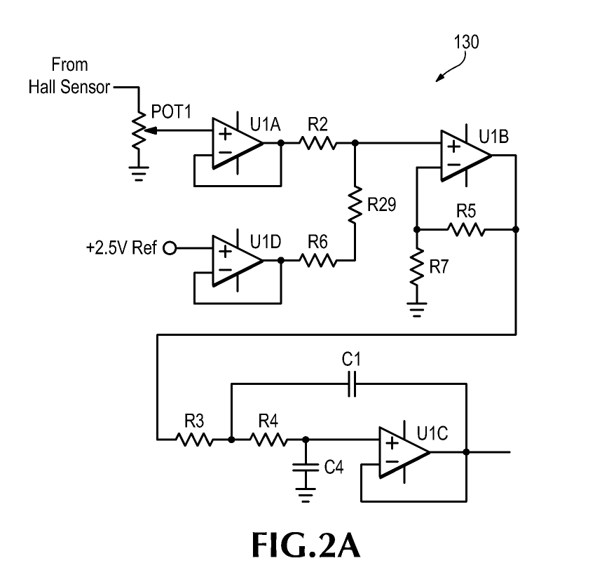

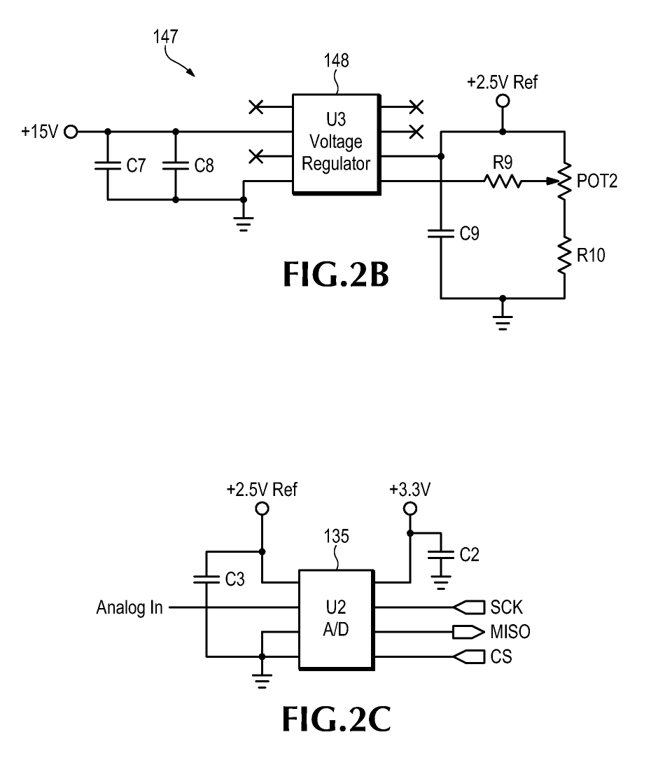

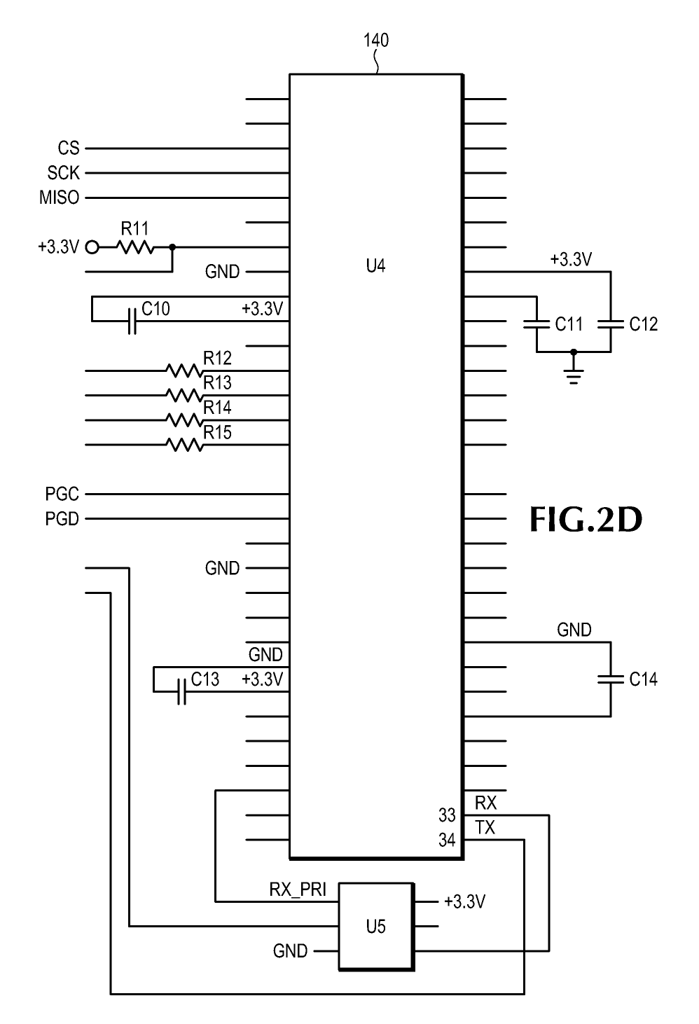

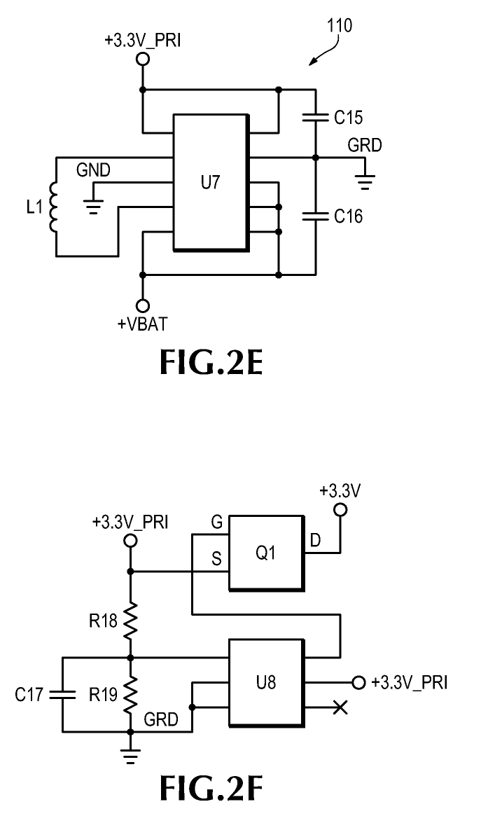

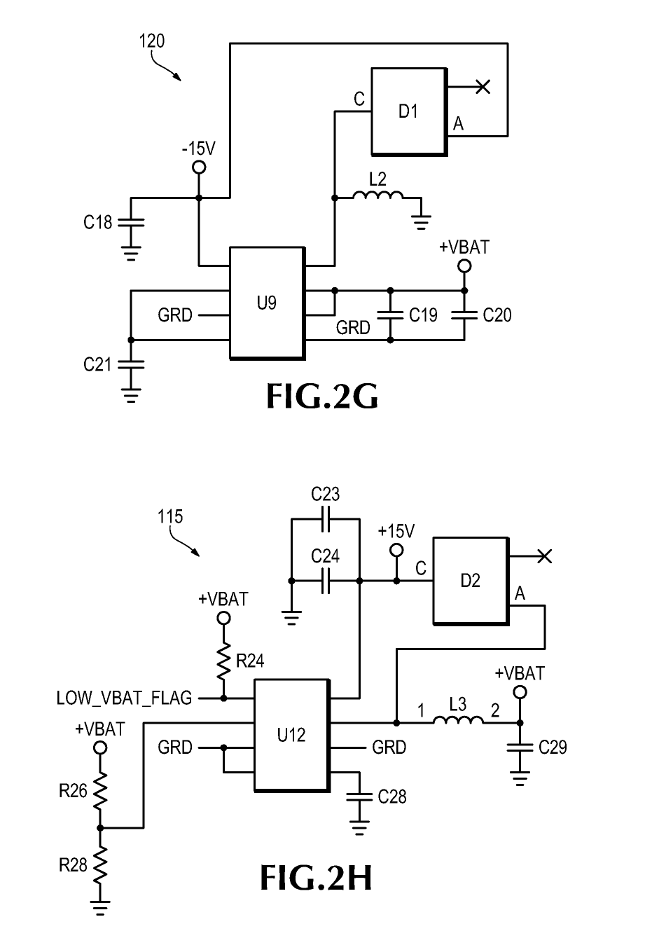

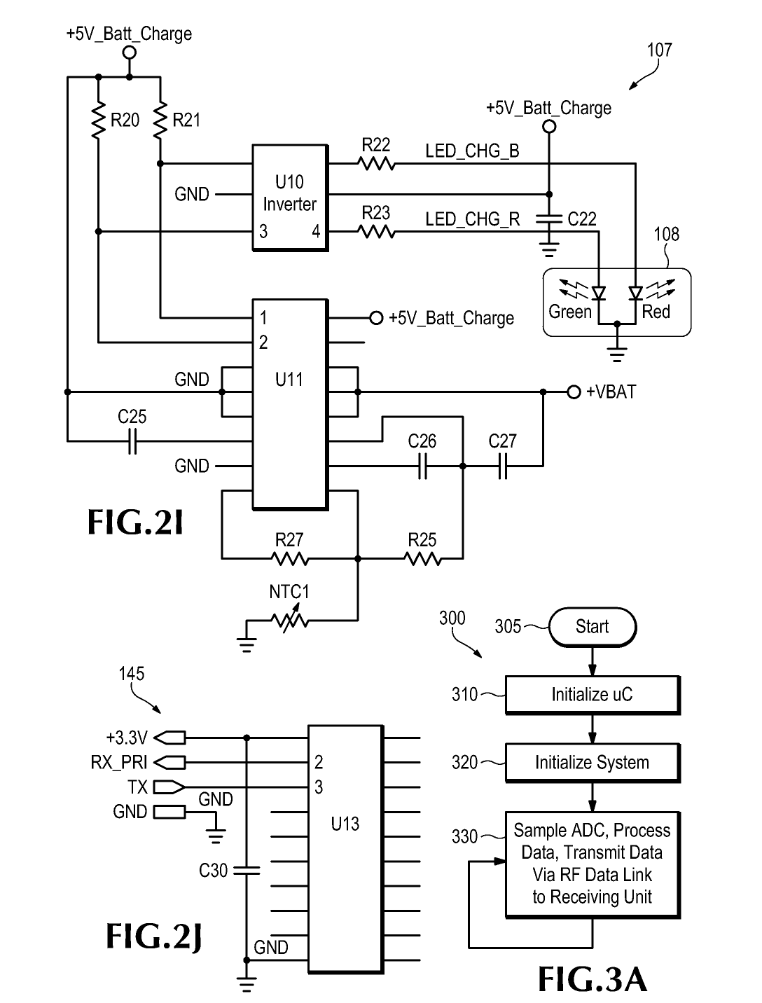

FIG. 2A is a schematic of one embodiment of an analog front end of the wireless clamp-on current probe transmitter of the subject invention. Potentiometer POT1 is used as an attenuator for the single-ended output signal of Hall Effect sensor 125. Small mechanical multi-turn potentiometers may be used, but in a preferred embodiment, potentiometer POT1 can be a solid state digital potentiometer which is more reliable.

An operational amplifier (Op-amp) U1A is used to buffer the attenuated Hall Effect sensor signal received from the wiper terminal of POT1. An Op-amp U1D is used to buffer the output from a +2.5V voltage reference 147. The output signals of Op-amps U1A and U1D are coupled to a further Op-amp U1B through a summing network composed of resistors R2, R6, and R29. Op-amp U1B and resistors R5 and R7 form an amplifier that is used to sum and scale the output signal of Op-amp U1A (i.e., the sensor signal), and the buffered +2.5V reference voltage from Op-amp U1D. The summed output of Op-amp U1B is now a signal which has been scaled and offset adjusted to optimize the use of the voltage input range of ADC 135 (U2 in FIG. 2C). The output signal of amplifier U1B is coupled to a filter comprising resistors R3, R4, capacitors C1 and C4 and a further Op-amp U1C. Op-amp U1C is configured as a second order low-pass filter which is used to limit the bandwidth of the signal that is to be applied to the input terminal of ADC 135.

FIG. 2B shows details of +2.5V voltage reference source 147. A voltage regulator 148 receives +15V at an input terminal and produces a regulated +2.5V voltage at its output terminal. Capacitors C7 and C8 filter the input voltage to eliminate unwanted noise. The regulated output voltage is applied to a voltage divider comprising resistors R9 and R10 and a potentiometer POT2. One skilled in the art will realize that potentiometer POT2 may also be of the solid state type, mentioned above. Adjustment of potentiometer POT2 causes the voltage developed at the +2.5V Ref output terminal to vary slightly. That is, the output of +2.5V voltage reference source 147 may be adjusted using POT2 of to slightly adjust the offset of the analog output signal at the input of Op-amp U1B of FIG. 2A.

Referring to FIG. 2C, ADC 135 is used to sample the conditioned output signal from the Hall Effect sensor 125 and convert it into 16-bit digital words which microcontroller 140 (U4 in FIG. 2D) can digitally process. Lower or higher resolution analog-to-digital converters could have been used, but the present cost and the resolution of a 16-bit ADC make it suitable for this application. Capacitors C2 and C3 filter the +3.3V supply and the +2.5V reference signal, respectively. ADC 135 may be, for example a LTC1864 manufactured by Texas Instruments.

Referring to FIG. 2D, microcontroller 140 controls all intelligent functions of the apparatus. All of the major integrated circuits onboard are designed to be controlled by and interfaced to a processor/microcontroller. The apparatus of the present invention can be designed to incorporate any of the various types of processors such as, but not limited to Complex instruction set computer (CISC), reduced instruction set computer (RISC), Harvard architecture, Von Neumann architecture and also the Modified Harvard architecture. A field programmable gate array (FPGA) or digital signal processor (DSP) also could have been used to implement the design. The preferred microcontroller has a small footprint, low pin count, ample program memory, low power consumption, integrated oscillator and rich set of peripherals and digital communication interfaces. Microcontroller 140 is responsible for polling the ADC at a regular time interval thus sampling the signal conditioned output from the Hall Effect sensor 125, it is used to compute the magnitude of the current being measured based on the data acquired from ADC 135, transmit current magnitude information to the system's RF transceiver U13, check the status of the system's battery, and interface with a host system to allow the end user to configure the system settings. Microcontroller 140 may be, for example, a DSPIC manufactured by Microchip Technology Inc. Single bus buffer gate/line driver U5 isolates the received signal output from RF transceiver (145 in FIG. 2J) from reaching the microcontroller 140 receive pin during system startup. A suitable single bus buffer gate/line driver is the SN74AHCT1G126 manufactured by Texas Instruments.

FIG. 2E is a more detailed illustration of +3.3V buck/boost switch-mode voltage regulator 110. A chip U7 used to convert the 4.2V-3.0V from lithium-ion battery 105 or from an external +5.0V supply, to a fixed +3.3V output voltage. A coil L1 is coupled to chip U7 and used in the switch mode regulation process. A capacitor C16 filters the incoming battery voltage and a capacitor C15 filters the +3.3V output voltage. This +3.3V “rail” (i.e., power supply level) is used to power microcontroller 140, ADC 135, and radio transceiver U13.

To prevent this switch-mode regulator from powering the previously mentioned circuits before the +3.3V output reaches steady-state, a “power-on-after-delay” circuit is implemented and is illustrated in FIG. 2F. The output of +3.3V regulator 110 is connected to the source terminal S of Q1, which may be an FET transistor switch, and also to a resistor/capacitor network which consists of R18, R19 and C17. When the output of the +3.3V regulator reaches steady-state and a period of time determined by the time constant of network R18 C17 has passed, the voltage level at an input of a inverter U8 is such that the output pin of inverter U8 will transition from +3.3V to 0V. When the gate terminal G of Q1 is low, the +3.3V (+3.3V_PRI) on its source terminal S will pass to the drain terminal D allowing the circuits on the +3.3V rail to be powered.

The switch-mode voltage regulators 120, 115 illustrated in FIG. 2G and FIG. 2H respectively, are used to bias the Hall Effect generator with +15.0V and −15.0V respectively. Referring to FIG. 2G, an integrated circuit switch-mode negative voltage regulator U9 receives the battery voltage from Li-Ion Battery Charge Management circuit 107, and provides −15V at its output terminal. Capacitors C19 and C20 filter the incoming conditioned battery voltage to remove noise, and capacitor C18 filters the generated −15V. Capacitor C21 and Inductor L2 are connected to terminals of integrated circuit switch mode voltage regulator U9 to ensure proper operation thereof. D1 is a Schottky diode which is used in conjunction with U9 to generate the −15.0V.

Referring to FIG. 2H, an integrated circuit switch-mode positive voltage regulator U12 receives the battery voltage from Li-Ion Battery Charge Management circuit 107, and provides +15V at its output terminal. Capacitors C23 and C24 filter the generated +15V. Capacitor C29 and Inductor L3 are connected to a terminal of integrated circuit switch mode positive voltage regulator U12 to ensure proper operation thereof. U12 in FIG. 2H can also provide the system microcontroller with battery status. When the system battery is drained below a certain predetermined threshold as measured at the common node between resistors R26 and R28, integrated circuit switch mode positive voltage regulator U12 pulls an output pin low (i.e., sinks current through a pull-up resistor R24) thereby signaling to the system microcontroller that the battery should be recharged soon. D2 is a Schottky diode which is used in conjunction with U12 to generate the −15.0V.

FIG. 2I shows additional details of Li-Ion Battery Charge Management circuit 107. Referring to FIG. 2I, an integrated circuit U11 is used to manage the charging of the system Lithium-Ion/Polymer battery 105. When an external supply of +5V is connected to the +5V_Batt_Charge terminal of unit 107, integrated circuits U10 and U11 are energized. In operation, charge management controller U11 receives the applied external +5V level and develops an appropriate voltage level to charge battery 105.

The charge management controller U11 initially checks the temperature of the battery via NTC1 (a negative temperature coefficient thermistor) which in conjunction with R27 forms a voltage divider circuit. Thermistor NTC1 is mounted in close proximity to Li-Ion battery 105 in order to sense the temperature of battery 105. As the battery temperature sensed by Thermistor NTC1 increases, its resistance decreases, causing a change in the voltage divider ratio, and a corresponding change in the voltage developed at the common node of thermistor NTC1 and resistor R27, which change of voltage is applied to an input terminal of charge management controller U11. If the temperature of the battery is within established limits, the charge cycle begins and pin number 2 of U11 is pulled low and pin number 1 is pulled high (i.e., controller U11 sinks current through a terminal coupled to pull-up resistor R20 and does not sink current through a terminal coupled to pull-up resistor R21). One end of resistors R20 and R21 are coupled together and to a +5V source. Resistors R20 and R21 have respective second ends coupled to respective input terminals of an inverter U10 for applying logic level signals thereto.

When pin number 3 of inverter U10 is pulled to a logic level low, pin number 4 is set high which will bias on the green element of the dual color LED (green/red) 108, causing current to flow through current limiting resistor R23. Illuminating the green portion of LED 108 signifies the battery is properly charging. The green portion of LED 108 will turn off when the charging cycle has successfully completed. If the temperature of the battery is too high, or too low, upon application of external power, the charge cycle is inhibited and pin number 2 of controller U11 is pulled high (extinguishing the green portion of LED 108) and pin number 1 alternates between high and low logic states at a rate of 1 Hz. This condition causes the red/green charge status LED 108 to blink red at a rate of 1 Hz. Capacitor C22 is coupled to, and filters, the +5V_Batt_Charge level, and capacitor C27 is coupled to, and filters, the battery voltage +VBAT. Capacitors C25 and C26 and resistor R25 are coupled to controller U11 and are used to ensure proper operation thereof.

FIG. 2J shows additional detail of RF Data Link 145. In one embodiment of the apparatus of the present invention, a Zigbee radio integrated circuit U13, illustrated in FIG. 2J, is used to wirelessly transmit the magnitude of the current being measured by the wireless clamp-on current probe to a receiving unit at regular intervals or, only when queried. Communications between microcontroller 140 and Zigbee radio chip U13 are handled via a simple logic-level universal asynchronous serial port interface (UART) on pins number 2 and 3 on Zigbee radio chip U13 and on pins number 33 and 34 on microcontroller 140. The interface is not only used to transmit data over the air to a receiving unit 400, but is also used to configure the Zigbee radio so that it may properly communicate with other Zigbee radios in a personal area network. Zigbee radio integrated circuit U13 may be a XB24-Z7WIT-004 manufactured by Digi International.

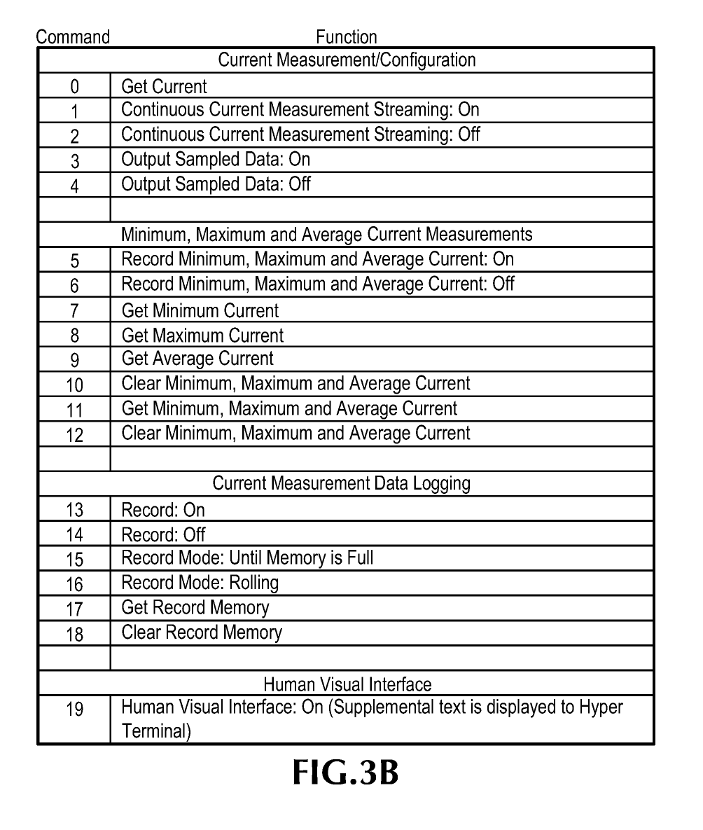

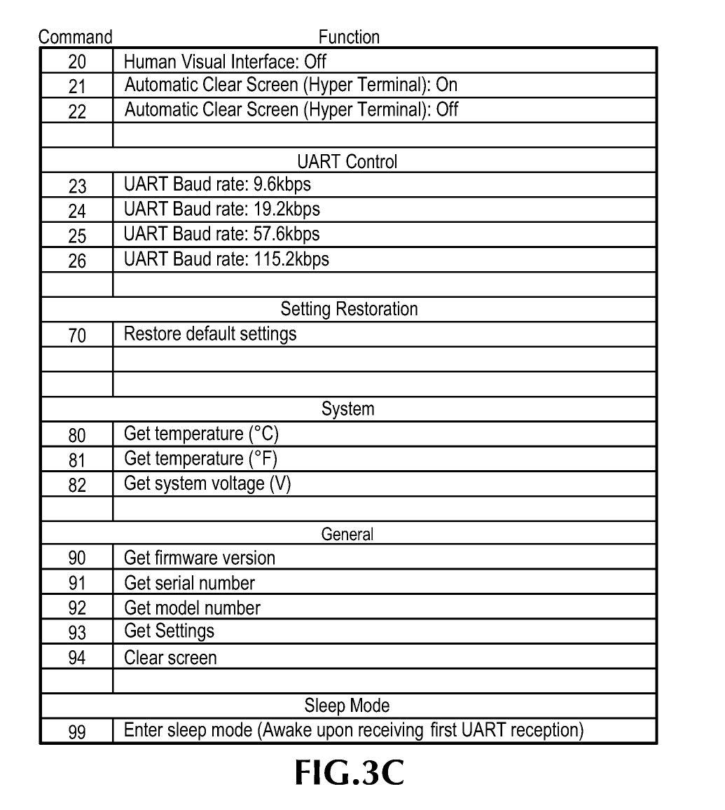

A basic firmware flowchart 300 of the wireless clamp-on current probe transmitter of the subject invention is illustrated in FIG. 3A. The routine is entered at step 305 and progresses to step 310 wherein microprocessor 140 is powered-up. Upon system power up at step 320, microcontroller 140 (U4 of FIG. 2D) initializes all of the input/output ports on the apparatus, initializes variables, reads and loads data coefficients from non-volatile memory, checks the battery status, and configures the Zigbee radio for use. At step 330, the clamp-on current probe will sample the output of the Hall Effect sensor with ADC 135, process the digitized data with microcontroller 140 and then, depending on the user configuration, the unit will then be on standby awaiting a command from the receiving unit or will check for an active receiver to send current measurements at a user defined regular interval or just idle until a current measurement sample is requested.

FIG. 4 shows a basic high-level block diagram of the receiver system 400 of one embodiment of the invention, which illustrates the relationship between all of the major sub-circuits of the system such as power, analog, digital and RF. The primary sources of power for the receiving unit are ±15Vpower supplies 410, 415 provided by the end-user. Because the voltages used by the subsystems need to be fixed a particular voltages, the use of voltage regulators may be required. The apparatus of the present invention include two +3.3V linear voltage regulators 420, 425 which supply the required constant voltages to all of the digital subsystems. An RF Data Link 430 receives the data which was transmitted by the clamp-on current probe and relays it to the system microcontroller 440 serially.

Microcontroller 440 formats the incoming data and serially transmits it to a digital- to-analog converter (DAC) 435. Microcontroller 440 is also responsible for handling a user interface 405. DAC 435 converts the incoming digital data from the microcontroller 440 to an analog signal. A signal conditioning circuit 445, in cooperation with a Voltage Reference circuit 450, then filters, shifts and amplifies the analog signal from DAC 435 so that it now represents the magnitude of the current signal measured by the wireless clamp-on probe transmitter and outputs the analog signal at an output circuit 455 for use by the end-user. The end-user may also retrieve the output signal in digital form that is produced by microcontroller 440.

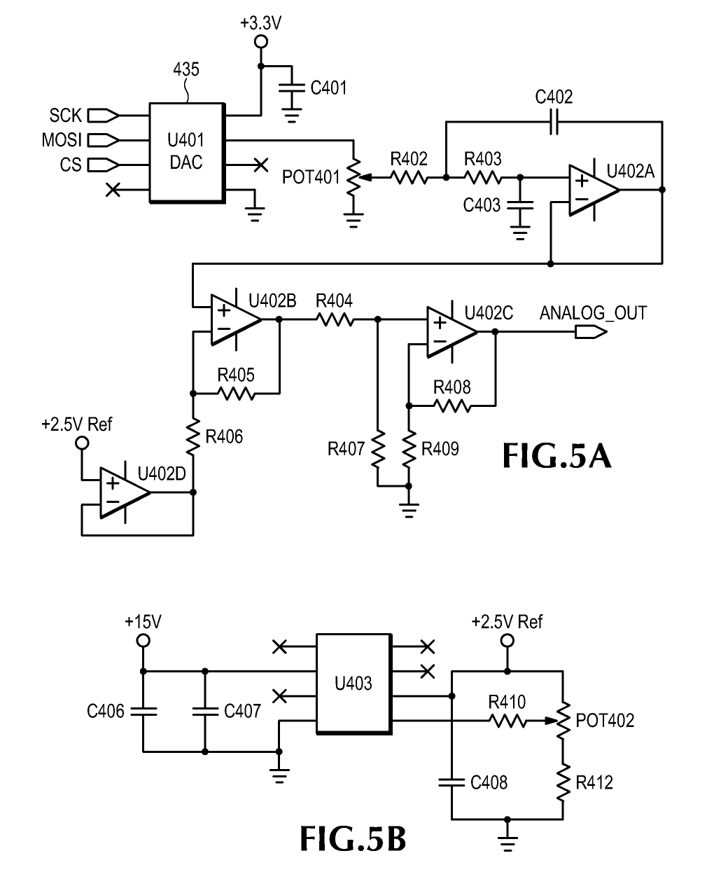

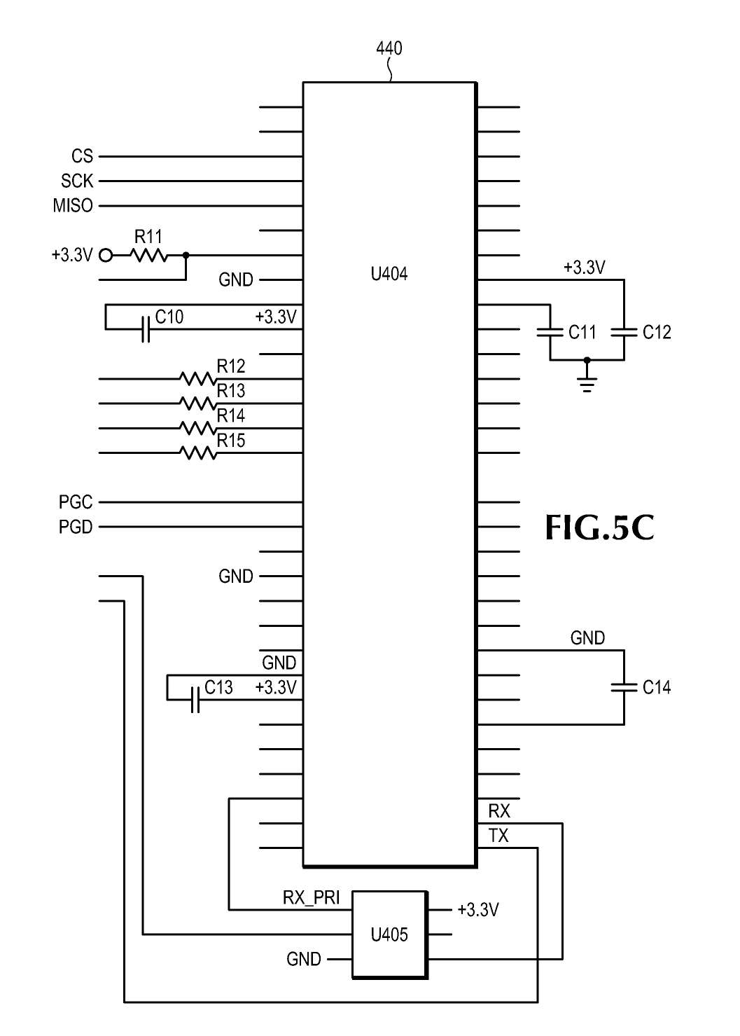

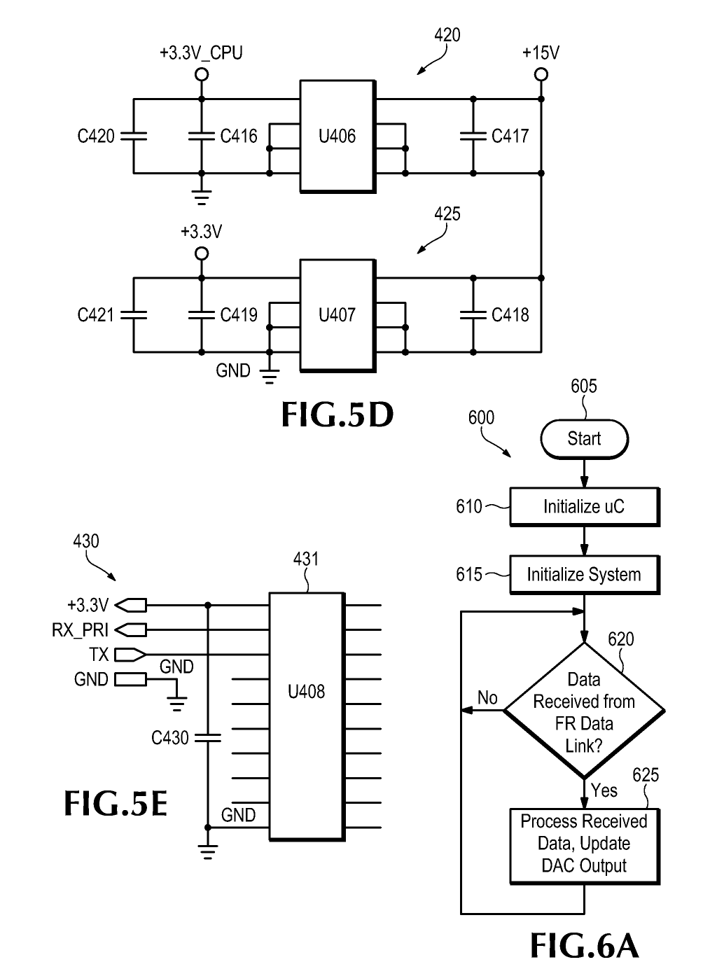

FIG. 5A is a schematic of the analog signal conditioning circuitry 445 of the wireless clamp-on current probe receiver unit 400. Potentiometer POT401 is used as an attenuator for the output signal from DAC 435. An Op-amp U402A in conjunction with resistors R402, R403 and capacitors C402 and C403 are configured as a second order low-pass filter (anti-imaging filter) which is used to limit the bandwidth of the DAC output signal before applying it to an input terminal of a second Op-amp U402B. Op-amp U402D is used to buffer the output from the +2.5V voltage reference 450 which is used to add offset to the output signal from DAC 435. The output of +2.5V voltage reference 450 may be adjusted using potentiometer POT402 of FIG. 5B to slightly adjust the offset of the analog output signal. Op-amp U402B is used to sum the outputs of U402A, the output signal of DAC 435, and the output signal of Op-amp U402D (the buffered +2.5V reference voltage). Resistors R404 and R407 form a voltage divider for scaling the conditioned analog signal. An amplifier circuit, including Op-amp U402C and gain-setting resistors R408 and R409, is used to amplify the output signal of Op-amp U402B. The output of Op-amp U402C is now a signal which has been scaled and offset and is the final analog output signal produced by receiving unit 400.

FIG. 5B shows details of +2.5V voltage reference source 450. A voltage regulator U403 receives +15V at an input terminal and produces a regulated +2.5V voltage at its output terminal. Capacitors C406 and C407 filter the input voltage to eliminate unwanted noise. The regulated output voltage is applied to a voltage divider comprising resistors R410 and R412 and a potentiometer POT402. One skilled in the art will realize that potentiometer POT402 may also be of the solid state type, mentioned above. Adjustment of potentiometer POT402 causes the voltage developed at the +2.5V Ref output terminal to vary slightly. That is, the output of +2.5V voltage reference source 450 may be adjusted using POT402 of to slightly adjust the offset of the analog output signal at the input of Op-amp U402D of FIG. 5A.

Microcontroller 440 in FIG. 5C controls all intelligent functions of the apparatus. All of the major integrated circuits onboard are designed to be controlled by and interfaced to a processor/microcontroller. Microcontroller 440 in the receiving unit is responsible for receiving data from the Zigbee radio via its UART, providing the digital data stream to DAC 435, controlling DAC 435 to provide an analog output signal to signal conditioning circuitry 445, optionally outputting data digitally via serial interface, and employing its UART interface to allow the user to configure the unit externally. Microcontroller 440 may be, for example, a DSPIC manufactured by Microchip Technology Inc. U405 of FIG. 5C is a single bus buffer gate/line driver.

FIG. 5D illustrates a pair of linear voltage regulators 420, 425 which are used to decrease the input voltage from the end user to a known and usable voltage. Voltage regulator U406 is a +3.3V regulator which is used to power microcontroller 440 and DAC 435. Voltage regulator U407 is also a +3.3V regulator and is used to power the Zigbee radio 430. Two discrete +3.3V voltage regulators are used instead of one to keep power dissipation for the voltage regulator integrated circuit at a minimum for each apparatus.

Referring to FIG. 5E, the subject receiver embodiment 400 uses a Zigbee radio 430, to wirelessly receive data indicative of the magnitude of the current being measured by the transmitting wireless clamp-on current probe. The apparatus can be configured so that the information is received/sent at regular intervals or only when queried. Communications between microcontroller 440 and Zigbee radio integrated circuit 431 are handled via a simple logic-level universal asynchronous serial port interface (UART) as described for the transmitting circuitry.

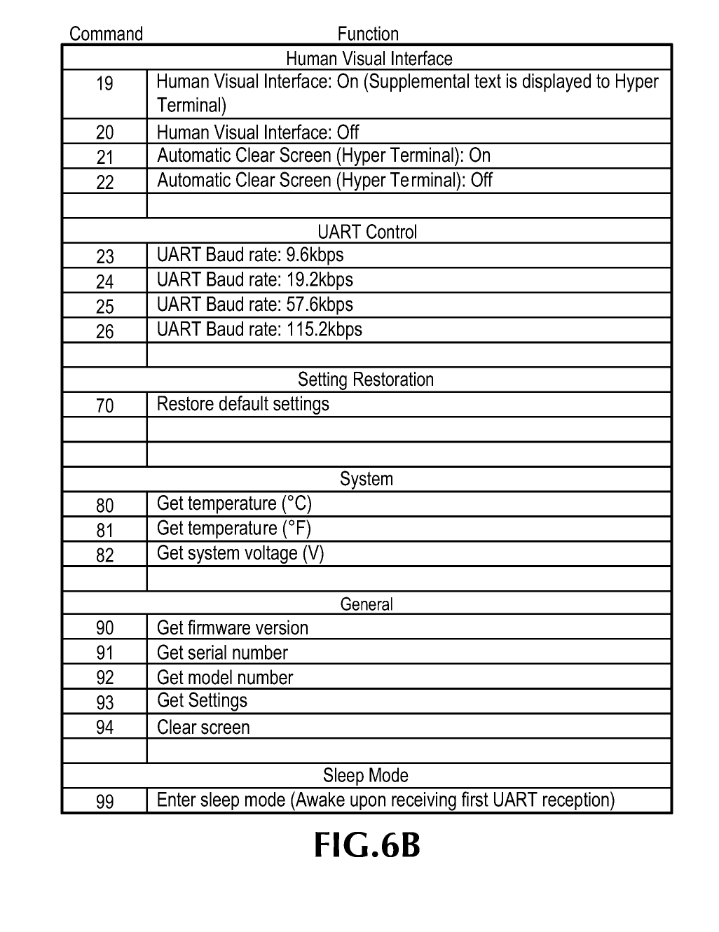

A basic firmware flowchart 600 for the wireless clamp-on current probe receiver 400 is illustrated in FIG. 6A. The routine is entered at step 605 and advances to step 610 wherein microcontroller 440 is initialized. Upon system power up at step 615, microcontroller 440 initializes all of the input/output ports on the apparatus, initializes variables, reads and loads data coefficients from non-volatile memory, and configures Zigbee radio 430 for use. Depending on the user configuration, the unit will then be on standby awaiting an interrogation command from the transmitting unit. If an interrogation command is received, the receiving unit will respond with a command received acknowledgement which allows for the transmitting unit to recognize that a receiving unit is active and ready to receive data. If the transmitting unit is set to stream data, the microcontroller of the receiving unit will receive a stream of data via UART from Zigbee radio 430 at step 620. Microcontroller 440 in turn will control DAC 435 to update the analog output signal or optionally output the received data digitally via serial communication.

Calibration of the apparatus involves the adjustment of gain and offset potentiometers POT1 and POT2 on the transmitting apparatus 100 and also POT401 and POT402 of the receiving apparatus 400 in accordance with this particular embodiment. In a preferred embodiment, the potentiometers would be replaced by digital potentiometers or programmable current sources or a combination of both allowing for the calibration of the apparatus by automated means.

In other embodiments of the present invention, +5V components may be used, requiring +5V analog and digital voltage rails. This embodiment may require relatively more power to operate. Alternatively, +1.8V electronic components, which have very low power requirements, can be employed. In a preferred embodiment, the selected digital and mixed signal components used are all low power +3.3V devices, such as CMOS devices.

Temperature compensation can be incorporated into the apparatus of the present invention to increase the accuracy of the current measurements, especially when the apparatus is to be used in an environment which significantly differs in temperature from the environment in which it was calibrated. For example, the output voltage at a given magnetic field level of most Hall Effect devices decreases as temperature rises. The output of a temperature sensing apparatus (thermistor, thermocouple or dedicated temperature sensing integrated circuit) could be used to compensate for the temperature coefficient of the output of the sensing elements (Hall Effect apparatus in the invention as presently designed). This compensation could be performed in the analog circuitry by altering the gain of the amplifier, or the control current level. Temperature compensation may also be performed mathematically by the microcontroller section of the apparatus of the present invention by using temperature coefficient data for the sensing elements, whether typical empirically-derived values or actual measured values. The temperature sensor may be digital and may be controlled and read by microcontroller 140.

The implementation of the circuitry for the apparatus of the present invention may be accomplished in various ways. For example, the GaAs Hall Effect sensors could also be InAs or InSb sensors or, alternatively other magnetic sensor types such as but not limited to, magneto-restive (MR/GMR), magneto-optical or coils may be used. Other communication schemes such as Ethernet or USB could be employed in addition to the preferred serial bus. The applications of the subject invention are not limited to the particular current measurement range limit, resolution, or accuracy described herein. Furthermore, the apparatus could be configured as a remote-monitoring apparatus, powered over Ethernet (POE), and controllable via the internet for application in any number of domestic, commercial or industrial locations.

A typical application in which the invention may be used is to wirelessly measure the current passing through a conductor on a distant apparatus using stationary test equipment. Another possible application is to measure and record the current consumption of multiple devices, which are separated by a distance of a few hundred feet using multiple wireless clamp-on current probes and one wireless current probe receiver connected to test and measurement equipment. Generally speaking, the typical application in which the invention may be used is bound only by the imagination of the end-user.

Communication with, and control of, the apparatus of the present invention may be achieved by use of a commercially available software language, for example but not limited to the variants of C, C++, BASIC, Fortran, LabView, TestPoint or HyperTerminal and a computer or controller which can send and receive serial communication signals or by other equipment with a serial port for communication. The communication may be at TTL type digital or bipolar voltage levels commonly associated with RS-232C interfaces. The default message terminator when sending a command to the unit is a carriage return (0x0D) and the default message terminator sent by the unit is line feed and carriage return (0x0D, 0x0A). Communication may be by direct wired connection or in conjunction with RF or optical transceiver modules. There are four user selectable baud rates available. Miscellaneous data such as model number, serial number or firmware version of the unit in operation may be retrieved by the user.

The internal data logging function is also user-configurable for various timing intervals and retrieval of data. Control may be initiated through text based command strings or graphical interfaces such as buttons or check boxes, limited only by the host system's particular programming language or hardware capabilities. The data received from the unit may be displayed numerically, graphically or stored in external memory of the host apparatus.

Communication may be achieved by use of a standard command set which may be expanded as future needs arise. Numeric commands are sent to the unit to change operating modes or to retrieve information back to the host. A command to clear the screen is included specifically for use with Microsoft HyperTerminal program. Other commands used for calibration are proprietary to the factory. This prevents the user from accidentally changing or corrupting the calibration of the unit. A standard user command set is described in FIGS. 3B, 3C and 6B.

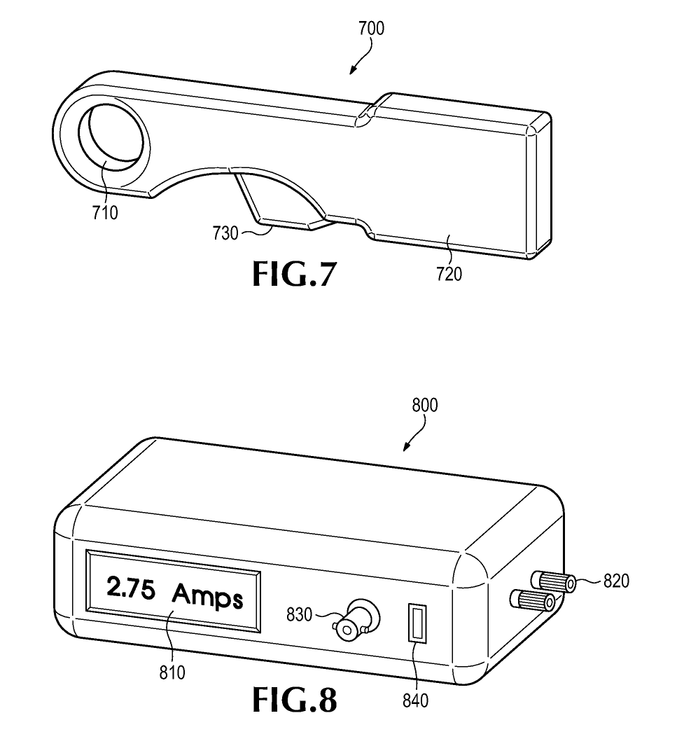

A perspective view of an embodiment of the clamp-on wireless current probe 700 of the subject invention is shown in FIG. 7, wherein a current carrying wire (not shown) passes through an aperture 710 in probe body 720 for measurement of the magnitude of the current.

A trigger 730 on probe body 720 is depressed by an end-user to open the aperture and place the apparatus around a conductor which is carrying a current that is to be measured. While the probe body 720, shown in FIG. 7, is suitable for use with the subject invention, one skilled in the art will realize that other suitable arrangements are equally usable.

A perspective view of a housing 800, suitable for use as an enclosure for the receiver 400 of the subject invention, is shown in FIG. 8. Receiver 400 may include a display 810 for displaying an indication of the current measured by Clamp-on Wireless Current Probe 700. Receiver 400 may also have one or more of a variety of connectors, such as: banana jacks 820, a BNC terminal 830, a USB terminal 840, or the like, for communicating measurements and setup data between receiver 400 and an external test and measurement instrument or an external computer (not shown). While the shape of enclosure 800 of FIG. 8 is suitable for use with the subject invention, one skilled in the art will readily understand that other suitable enclosures may be used.

The conjunctive article “or” as used herein, is used in the inclusive-or sense (i.e., one or the other or both). Moreover, it is intended to convey the meaning that either alternative is sufficient, and that all stated alternatives do not have to be present.

The embodiments described herein are for purposes of explanation, and are not intended to be limiting in any way. The subject invention is intended to be limited only by the following claims.

We claim:

1. A wireless clamp-on current probe, comprising:
a battery supplying power to said wireless clamp-on current probe;
a voltage regulator coupled to said battery and producing a power supply voltage at an output terminals;
a transducer, responsive to a magnetic field, for producing a signal representative of current conveyed by a conductor under test;
signal conditioning circuitry for offsetting and scaling said signal representative of said current to produce a conditioned signal;
an analog-to-digital converter for sampling said conditioned signal to produce digital signal samples;
a microcontroller controlling said analog to digital converter and for processing said digital signal samples; and
a radiofrequency data link for communicating between said microcontroller and a receiver unit, said radio frequency data link operating under control of said microcontroller.

2. The wireless clamp-on current probe of claim 1, wherein said voltage regulator is a switch-mode voltage regulator.

3. The wireless clamp-on current probe of claim 2, wherein said transducer is a Hall Effect sensor.

4. The wireless clamp-on current probe of claim 3, wherein said signal conditioning circuitry includes a user adjustable device for adjusting said offset.

5. The wireless clamp-on current probe of claim 4 wherein said battery is a lithium-ion battery.

6. A method of making noncontact current measurements of current passing through a conductor without interrupting the electrical circuit being tested and wirelessly transmitting the measurements to a receiving unit, comprising the steps of:
clamping a wireless clamp-on current probe around said conductor;
detecting a magnetic field generated by said current carrying conductor;
generating a voltage representative of a magnitude of said current in response to detection of said magnetic field;
scaling a magnitude of said voltage;
sampling said voltage and producing digital data representing said samples;
formatting said digital data; and
sending the data to a receiving unit.

7. The method of claim 6, wherein the step of:
generating a voltage representative of a magnitude of said current is accomplished by use of a Hall Effect sensor.

8. The method of claim 6, wherein the step of formatting of said digital data is accomplished by use of a microcontroller.

9. A wireless clamp-on current probe and receiver system, comprising:
a wireless clamp-on current probe assembly, including:
a battery supplying power to said wireless clamp-on current probe;
a voltage regulator coupled to said battery and producing a power supply voltages at an output terminal;
a transducer, responsive to a magnetic field, for producing a signal representative of current conveyed by a conductor under test;
signal conditioning circuitry for filtering said signal representative of said current to produce a conditioned signal;
an analog-to-digital converter for sampling said conditioned signal to produce digital signal samples;
a microcontroller controlling said analog to digital converter and for processing said digital signal samples; and
a radiofrequency data link for communicating between said microcontroller and a receiver unit, said radio frequency data link operating under control of said microcontroller;
and
said receiver unit, said receiver unit including:
a radio frequency receiver for receiving said digital data signal samples from said probe;
a microcontroller coupled to said radio frequency receiver for receiving and processing said digital data signal samples;
a digital-to-analog converter for converting said processed digital signal samples to an analog waveform representative of the current conveyed by said conductor under test, said digital-to-analog converter operating under control of said microcontroller;
signal conditioning circuitry coupled to the output of said digital-to analog converter for receiving and filtering said analog waveform; and
an output terminal for providing said filtered analog waveform to an external test and measurement instrument or to an external computer.

10. The wireless clamp-on current probe and receiver system of claim 9, wherein
said receiver includes a display device for displaying an indication of said magnitude of said current conveyed by said conductor under test.

11. The wireless clamp-on current probe and receiver system of claim 9, wherein
said receiver includes connectors for providing said filtered analog waveform to an external test and measurement instrument or to an external computer.
